(19) United States
(12) Patent Application Publication
(10) Pub. No.: US 2010/0142132 A1
(43) Pub. Date: Jun. 10, 2010

(54) SLIDABLE HOUSING FOR AN ELECTRONIC DEVICE

(75) Inventors: Pekka Markus Kilpi, Helsinki (FI); Anssi Ilmari Vanska, Helsinki (FI); Ilpo Kalevi Kauhaniemi, Vantaa (FI)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/521,115

(22) PCT Filed: Dec. 29, 2006
(86) PCT No.: PCT/EP2006/012594

§ 371 Date: Jan. 11, 2010

(51) Int. Cl. H05K 5/00; A47B 81/00

(52) U.S. Cl. 361/679.01; 312/223.1

(57) ABSTRACT

An apparatus (10) for an electronic device, the apparatus comprising a sliding mechanism arranged to slide a first and a second housing between retracted and extended configurations, wherein the first housing (11) comprises first and second opposing faces (14, 15); the second housing (12) comprises a first face (13) having a first portion (13a) and a second portion (13b, 13c); and wherein the apparatus (10) is arranged such that, in the retracted configuration, the first and second portions (13a, 13b, 13c) of the first face (13) of the second housing (12) are hidden by the second face (15) of the first housing (11) and, in the extended configuration, the first portion (13a) of the first face (13) of the second housing (12) is revealed and displaced relatively away from the second face (15) of the first housing (12) and relatively towards the first face (14) of the first housing (11), and the second portion (13b, 13c) of the first face (13) of the second housing (12) is hidden by the first housing (11); and wherein the apparatus comprises one or more magnetic elements (16a, 16b, 17a, 17b) arranged to bias and/or hold the first and second housings (11, 12) between/in one or more of the retracted and extended configurations.

The invention relates to an apparatus for an electronic device, in particular for an extensible mobile electronic device such as a hand-portable radio telephone.

### BACKGROUND

In the field of mobile telecommunications, various mechanisms are known that allow for foldable and sliding devices. WO 2006/106374, for example, discloses a sliding mechanism for an extensible mobile electronic device having a retracted and extended position.

A problem with previous solutions is that of holding the device in either or both of the retracted and extended positions.

The listing or discussion of a prior-published document in this specification should not necessarily be taken as an acknowledgement that the document is part of the state of the art or is common general knowledge.

### SUMMARY

According to the invention, there is provided an apparatus for an electronic device, the apparatus comprising a first housing, a second housing, and a sliding mechanism arranged to slide the first and second housings between a retracted configuration and an extended configuration, wherein
the first housing comprises first and second opposing faces;
the second housing comprises a first face having a first portion and a second portion; and
wherein the apparatus is arranged such that,
in the retracted configuration, the first and second portions of the first face of the second housing are hidden by the second face of the first housing and,
in the extended configuration, the first portion of the first face of the second housing is revealed and displaced relatively away from the second face of the first housing and relatively towards the first face of the first housing and the second portion of the first face of the second housing is hidden by the first housing and wherein the apparatus comprises one or more magnetic elements to bias and/or hold the first and second housings one or more of the retracted and extended configurations.

In this way, apparatus of the invention may be held in place in the retracted and/or extended configuration by attraction of the magnetic elements.

The present invention includes one or more aspects, embodiments and/or features of said aspects and/or embodiments in isolation and/or in various combinations whether or not specifically stated (including claimed) in that combination or in isolation.

### BRIEF DESCRIPTION OF THE DRAWINGS

A description is now given, by way of example only, with reference to the accompanying drawings, in which:

FIG. 1 is a cross-sectional schematic view of an apparatus in a retracted configuration;

FIG. 2 a cross-sectional schematic view of an apparatus in an intermediate configuration; and

FIG. 3 a cross-sectional schematic view of an apparatus in an extended configuration.

### DETAILED DESCRIPTION

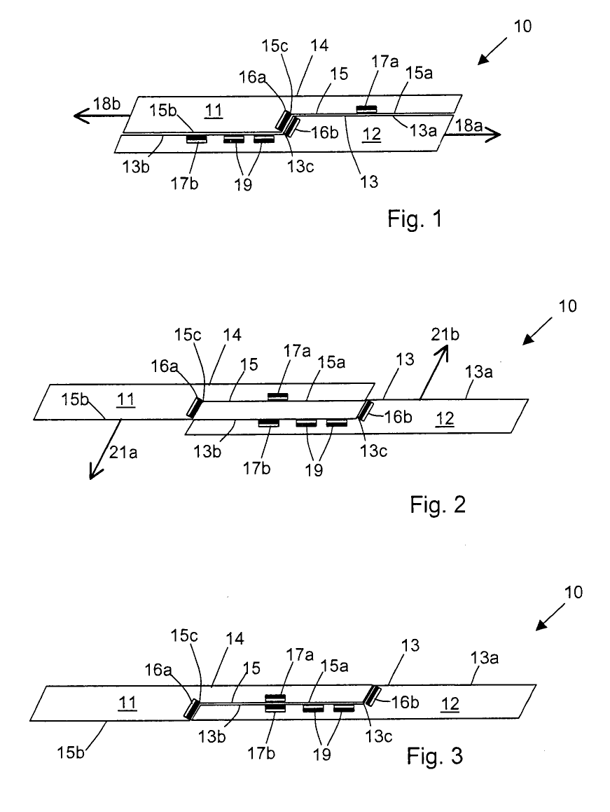

Apparatus in the form of a pair of housings 11, 12 is shown schematically in cross-section in FIG. 1. The apparatus 10 is shown in this figure in a retracted or stowed configuration. A first housing 11 has a first face 14 and a second opposing face 15, the second face 15 comprising a first portion 15a and a second portion 15b, the first and second portions in this embodiment being contiguous with and joined by a stepped portion 15c. The second portion 15b lies in a plane that is displaced through the thickness of the apparatus 10 in a direction orthogonal to the first portion 15a. The stepped portion 15c comprises a mating surface, the shape of which may be flat or curved.

It is to be understood that the first and second portions 14, 15 may alternatively be curved in shape, provided that their degree of curvature is substantially similar or matching.

A second housing 12 has a first face 13, which in this embodiment is subdivided into a first portion 13a and a second portion 13b, the second portion having a stepped portion 13c.

In the retracted configuration, the first portion 13a of the first face 13 of the second housing 12 is adjacent to and facing the first portion 15a of the second face 15 of the first housing 11. Part of the second portion 13b of the first face 13 of the second housing 12 is adjacent to and facing the second portion 15b of the second face 15 of the first housing 11. The stepped portion 15c of the first housing 11 is adjacent to and facing the stepped portion 13c of the second housing 12.

In a general aspect, in the retracted configuration the first and second portions 13a, 13b, 13c of the first face 13 of the second housing 12 are hidden by the second face 15 of the first housing 11.

Provided on or proximate the surfaces 15, 13 of the first and second housings 11, 12 are one or more magnetic elements 16a, 16b, 17a, 17b. In the retracted configuration, magnetic elements 16a, 16b engage with each other by mutual attraction across the adjoining stepped portions 13c, 15c. In the figure, the polarity of the magnetic elements is indicated by a shaded portion and an unshaded portion. For the purpose of illustrating the embodiment, the shaded portion of each magnetic element is to be taken to be the north pole of the magnet, and the unshaded portion the south pole. However, the absolute orientation of the magnetic elements may be in any direction, provided the relative orientations remains substantially as shown. For example, the magnetic elements may all be reversed in polarity without departing from the functionality of the embodiment shown.

In the retracted configuration, the north pole of magnetic element 16b on or proximate the stepped portion 13c of the second housing 12 is adjacent the south pole of magnetic element 16a on or proximate the stepped portion 15c of the first housing 11. The mutual attraction between these magnetic elements 16a, 16b provides an attractive force resisting separation of the first and second housings 11, 12.

It is to be understood that any suitable type of magnetic element may be used. Alternative embodiments may include pairs of magnetic elements comprising a permanent magnetic element and a ferromagnetic material element (e.g. composed of ferritic steel or nickel). Many types of magnetic materials may be suitable, for example ferritic composition magnets or compositions comprising neodymium iron boride or samarium cobalt. A further possible alternative is the use of electromagnets for one or more of the magnetic elements 16a, 16b, 17a, 17b.

The apparatus 10 is provided with a slide mechanism (not shown) to allow relative sliding of the first and second housings 11, 12 in the directions indicated in FIG. 1 by arrows 18a, 18b (and directions 21a, 21b of FIG. 2, including the reverse directions for 18a, 18b, 21a, 21b). Such a sliding mechanism may be of any type, including those disclosed in WO 2006/106374.

Separation of the housings 11, 12 in the directions indicated is initially resisted by attraction between the magnetic elements 16a, 16b. Once this attraction is overcome the housings 11, 12 freely slide relative to each other.

Shown in FIG. 2 is an intermediate configuration in which the housings 11, 12 are shown in a position after relative sliding from the retracted position. In this configuration, magnetic elements 16a, 16b are no longer providing a significant relative attraction. Magnetic elements 17a, 17b are provided on or proximate the first portion 15a of the first face of the first housing 11 and the second portion 13b of the first face 13 of the second housing 12. These magnetic elements 17a, 17b begin to provide a relative attraction between the facing portions 13b, 15a of the housings 11, 12 in this configuration, since the north pole of one magnetic element 17b is facing the south pole of the other magnetic element 17a.

The sliding mechanism (not shown) of the apparatus 10 allows for relative movement between the housings from the intermediate configuration of FIG. 2 in the directions indicated by arrows 21a, 21b.

After relative movement in the directions 21a, 21b indicated, the apparatus reaches an extended configuration, shown in FIG. 3. In this configuration, magnetic elements 17a, 17b provide a mutually attractive force between facing portions 13b, 15a of the first and second housings 11, 12, this force resisting separation of the housings 11, 12 from the extended configuration.

In the extended configuration therefore, the first portion 13a of the first face 13 of the second housing 12 is revealed and displaced relatively away from the second face 15 of the first housing 11 and relatively towards the first face 14 of the first housing 11, and the second portion 13b, 13c of first face 13 of the second housing 12 is hidden by the first housing 11.

In the embodiment shown, the second portion 13b is, in use, always hidden from view, whereas the first portion 13a is revealed when the apparatus 10 is in the extended configuration of FIG. 3, and is hidden from view when the apparatus 10 is in the retracted configuration of FIG. 1.

A user interface, for example a screen and/or a keypad, may be provided on the first portion 13a of the second housing, this user interface being revealed when the apparatus is in the extended configuration of FIG. 3.

Further magnetic elements 19 may additionally be provided on or proximate a portion of the first and/or second housings 11, 12. For example, the magnetic elements illustrated in the figures are provided proximate the second portion 13b of the second housing 12. The orientation of the magnetic elements 19 is such that they are arranged to repel the magnetic element 17a provided on the first housing 11. This repulsion may allow for an improved sliding action when the housings 11, 12 are sliding relative to one another between the retracted configuration of FIG. 1 and the intermediate configuration of FIG. 2.

In one embodiment, the magnetic elements 16a, 16b may be arranged to overlie one another in the retracted configuration. In another embodiment, the magnetic elements 16a, 16b may be arranged to not overlie one another in the retracted configuration and may be laterally spaced apart (in and out of the paper in FIG. 1). Similarly, one or more other magnetic element pairs may be arranged to overlie or not overlie one another in the retracted and/or extended configurations. The orientation of one or more of the magnetic elements do not necessarily have to be aligned with the face to which they are adjacent. For example, the magnetic elements 16, 16b may be arranged to be perpendicular to the longitudinal axis of the apparatus 10 (not shown) rather than be aligned to be parallel to the portions 15c, 13c of faces 15 and 13 (as shown in FIG. 1).

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

While there have been shown and described and pointed out fundamental novel features of the invention as applied to preferred embodiments thereof, it will be understood that various omissions and substitutions and changes in the form and details of the devices and methods described may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto. Furthermore, in the claims means-plus-function clauses are intended to cover the structures described herein as performing the recited function and not only structural equivalents, but also equivalent structures. Thus although a nail and a screw may not be structural equivalents in that a nail employs a cylindrical surface to secure wooden parts together, whereas a screw employs a helical surface, in the environment of fastening wooden parts, a nail and a screw may be equivalent structures.

1. An apparatus for an electronic device, the apparatus comprising a first housing, a second housing, and a sliding mechanism arranged to slide the first and second housings between a retracted configuration and an extended configuration, wherein
the first housing comprises first and second opposing faces;
the second housing comprises a first face having a first portion and a second portion; and
wherein the apparatus is arranged such that[,] in the retracted configuration, the first and second portions of the first face of the second housing are hidden by the second face of the first housing and,
in the extended configuration, the first portion of the first face of the second housing is revealed and displaced relatively away from the second face of the first housing and relatively towards the first face of the first housing, and the second portion of the first face of the second housing is hidden by the first housing; and
wherein the apparatus comprises one or more magnetic elements arranged to bias and/or hold the first housing and the second housings in one or more of the retracted and extended configurations and one or more magnetic elements arranged to bias the first and second housings between the retracted and extended configurations.

2-16. (canceled)

17. An apparatus according to claim 1, wherein the first and second portion of the first face of the second housing are joined by a stepped portion, the stepped portion extending in a plane different to that of the first portion and the second portion, the stepped portion comprising one or more magnetic elements arranged to hold the first housing and the second housing in the retracted configuration, configured such that, in use, the one or more magnetic elements are pulled apart from corresponding magnet elements on the first housing, so as to allow for the extended configuration.

18. An apparatus according to claim 1, wherein the first portion of the first face of the second housing and the first face of the first housing lie substantially in the same plane in the extended configuration.

19. An apparatus according to claim 1, wherein one or more of the magnetic elements are provided with the second housing proximal to the second portion of the first face of the second housing.

20. An apparatus according to claim 1, wherein the first housing substantially overlies the second housing in the retracted configuration.

21. An apparatus according to claim 1, wherein the second face of the first housing comprises corresponding first and second portions to the first and second portions of the second housing and wherein the second portion of the first face of the second housing is displaced relatively towards the first portion of the second face of the first housing in the extended configuration.

22. An apparatus according to claim 1, wherein one or more of the magnetic elements are electromagnetic.

23. An apparatus according to claim 1, further comprising a user interface on the first face of the first housing.

24. An apparatus according to claim 1, further comprising a user interface on the first portion of the first face of the second housing.

25. An apparatus according to claim 1, further comprising a user interface on the first portion of the first face of the second housing, wherein the user interface is a user input interface.

26. An apparatus according to claim 1, wherein the one or more magnetic elements are permanently magnetic.

27. An apparatus according to claim 1, wherein the one or more magnetic elements are ferromagnetic.

28. An apparatus according to claim 1, wherein the apparatus is an electronic device.

29. An apparatus for an electronic device comprising a first means for housing, a second means for housing, and a means for sliding arranged to slide the first and second means for housings between a retracted configuration and an extended configuration, wherein:
the first means for housing comprises first and second opposing faces;
the second means for housing comprises a first face having a first portion and a second portion; and
wherein the apparatus is arranged such that in the retracted configuration, the first and second portions of the first face of the second means for housing are hidden by the second face of the first means for housing; and,
in the extended configuration, the first portion of the first face of the second means for housing is revealed and displaced relatively away from the second face of the first means for housing and relatively towards the first face of the first means for housing, and the second portion of first face of the second means for housing is hidden by the first means for housing; and
wherein the apparatus comprises one or more means for magnetically biasing/holding the first and second means for housings between/in the retracted and extended configurations.

30. A method, comprising:
providing a first housing comprising first and second opposing faces;
providing a second housing comprising a first face having a first portion and a second portion;
providing a sliding mechanism arranged to allow for sliding of the first and second housings between a retracted configuration and an extended configuration
configuring the first/second housing and slide mechanisms such that when in the retracted configuration, the first and second portions of the first face of the second housing are hidden by the second face of the first housing and in the extended configuration, the first portion of the first face of the second housing is revealed and displaced relatively away from the second face of the first housing and relatively towards the first face of the first housing, and the second portion of the first face of the second housing is hidden by the first housing;
providing one or more magnetic elements; and
configuring the one or more magnetic elements such that they hold the first/second housing in one or more of the retracted and extended configurations and configuring one or more magnetic elements such that they bias the first and second housings when being moved between the retracted and extended configurations.
